(19) United States
(12) Patent Application Publication
(10) Pub. No.: US 2019/0280498 A1
(43) Pub. Date: Sep. 12, 2019

(54) CHARGING SYSTEM

(71) Applicant: MITSUBISHI ELECTRIC CORPORATION, Tokyo (JP)

(72) Inventor: Takuto SUZUKI, Tokyo (JP)

(73) Assignee: MITSUBISHI ELECTRIC CORPORATION, Tokyo (JP)

(21) Appl. No.: 16/346,366

(22) PCT Filed: Nov. 28, 2016
(86) PCT No.: PCT/JP2016/085148

§ 371 Date: Apr. 30, 2019

(51) Int. Cl. H02J 7/00; B60L 53/16; G01R 31/392

(52) U.S. Cl. CPC H02J 7/0027; G01R 31/392; B60L 53/16

(57) ABSTRACT

A charging system includes a charger that charges an EV by converting power, and a charging connector that supplies power output from the charger to the EV, where the charger includes a connection count detector that detects the number of times the charging connector is connected to the EV, and a life determiner that determines whether or not the charging connector has reached end of life on the basis of at least the number of times the charging connector is connected as detected by the connection count detector.

### FIELD

The present invention relates to a charging system connected to an electric vehicle.

### BACKGROUND

In recent years, the number of charging stations installed in public facilities has increased with the spread of electric vehicles (EVs). Moreover, vehicle to home (V2H) which is a system for supplying power of EVs to home appliances in homes has attracted attention, so that charger/dischargers as well as chargers are expected to spread further in the future.

A charging connector that connects an EV to a charging device is a part through which a large current flows and which requires a high level of safety as a user directly touches the connector and connects the connector to the EV. In particular, a charging cable connected to the charging connector is often laid outdoors so that a part used in the charging cable possibly deteriorates further depending on the use environment, and thus the way of thinking toward the life of the charging cable is important.

As ways to determine the life of a charging cable, Patent Literature 1 discloses: a technique related to a method of counting the number of times a charging cable is inserted and removed; and a technique related to a method of detecting an abnormality such as heat generation using a temperature sensor. A charging system disclosed in Patent Literature 1 includes a charger, which includes a controller that performs various controls and a receptacle into which a plug as a power receiving connector of a vehicle is inserted. The controller detects the number of times the plug is inserted/removed into/from the receptacle on the basis of a change in impedance of a measurement object.

### CITATION LIST

### Patent Literature

Patent Literature 1: Japanese Patent No. 5855894

### SUMMARY

### Technical Problem

Although the charging system disclosed in Patent Literature 1 is configured to detect the number of times the plug is inserted/removed into/from the receptacle, Patent Literature 1 makes no mention of the number of times a charging connector is inserted/removed into/from a charging port (vehicle power receiving part) provided on the EV. The number of times the charging connector is inserted/removed is related to the life of the charging connector, whereby it has been desired to develop a charging system that can improve safety by preventing occurrence of an abnormality due to wear and deterioration of a part making up the charging connector.

The present invention has been made in view of the above, and an object of the present invention is to provide a charging system that can improve safety of a charging connector.

### Solution to Problem

To solve the above problems and achieve the object a charging system according to the present invention includes: a charger to charge an electric vehicle; and a charging connector to supply power output from the charger to the electric vehicle. The charger includes: a connection count detector to detect a number of times the charging connector is connected to the electric vehicle; and a life determiner to determine whether or not the charging connector has reached end of life on the basis of at least the number of times the charging connector is connected as detected by the connection count detector.

### Advantageous Effects of Invention

The charging system according to the present invention has an effect of improving safety of the charging connector.

### BRIEF DESCRIPTION OF DRAWINGS

FIG. 1 is a block diagram of a charging system according to a first embodiment.

FIG. 2 is a block diagram of a controller of a charger included in the charging system according to the first embodiment.

FIG. 3 is a sectional view of a charging connector and a charging cable included in the charging system according to the first embodiment.

FIG. 4 is a sequence chart of charging connector state detection processing performed in the charging system according to the first embodiment.

FIG. 5 is a flowchart of charging connector life determination processing performed in the charging system according to the first embodiment.

FIG. 6 is a block diagram of a controller of a charger included in a charging system according to a second embodiment.

FIG. 7 is a sequence chart of charging connector state detection processing performed in the charging system according to the second embodiment.

FIG. 8 is a flowchart of charging connector life determination processing performed in the charging system according to the second embodiment.

### DESCRIPTION OF EMBODIMENTS

A charging system according to embodiments of the present invention will now be described in detail with reference to the drawings. Note that the present invention is not limited to the embodiments.

### First Embodiment

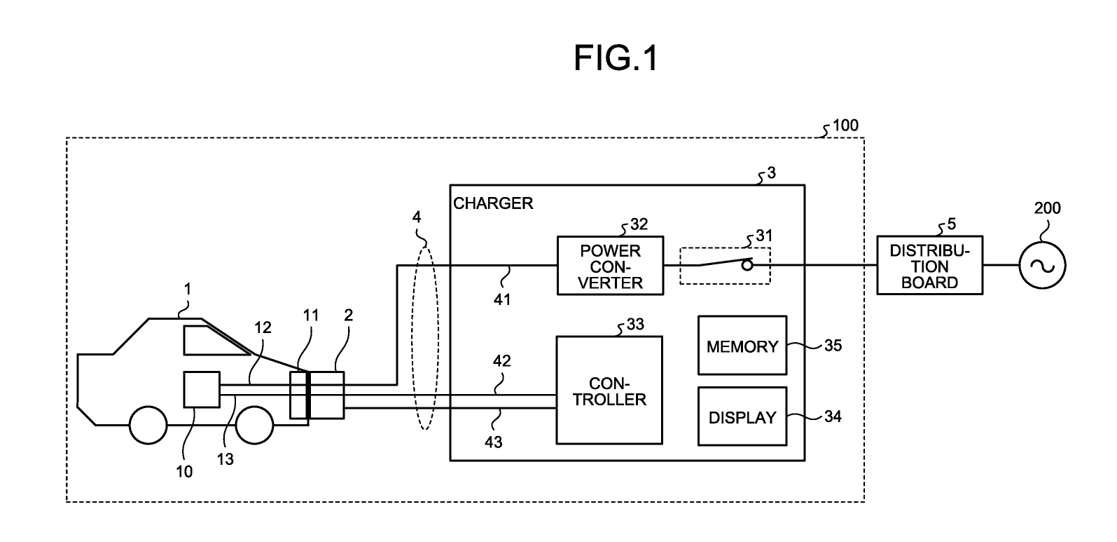

FIG. 1 is a block diagram of a charging system according to a first embodiment. A charging system 100 includes: an EV 1; a charging connector 2 connected to the EV 1; a charger 3 for charging the EV 1 with power supplied from a power system 200; and a charging cable 4 wired between the charger 3 and the charging connector 2. Note that the charging system 100 according to the first embodiment can be connected to a plug-in hybrid electric vehicle (PHEV) instead of the EV 1.

The EV 1 includes: a power supply 10 mounted in the EV 1; a vehicle power receiving part 11 to which the charging connector 2 is connected to be connected to a power line 41 which is an external power line for charging; a power line 12 connected between the power supply 10 and the vehicle power receiving part 11 to supply power from the vehicle power receiving part 11 to the power supply 10; and a signal line 13 wired between the power supply 10 and the vehicle power receiving part 11. The signal line 13 is a communication line that transmits a signal for confirming connection of a charge/discharge connector, and is connected to a signal line 42 via the vehicle power receiving part 11. Hereinafter, the signal for confirming connection of a charge/discharge connector may be simply referred to as a “connection confirmation signal”.

The charger 3 has a function of supplying power supplied from the power system 200 via a residential distribution board 5 to the EV 1 using the power line 41. Specifically, the charger 3 includes: an interconnection switch 31 connected to the distribution board 5; a power converter 32 connected to the interconnection switch 31 for converting AC power supplied from the power system 200 into DC power and outputting the power to the power line 41; a controller 33 including a function of detecting a state of the charging connector 2; a display 34 for informing a user that the charging connector 2 has reached end of life when a life determiner (to be described) determines that the charging connector 2 has reached the end of life; and a memory 35 for storing the state of the charging connector 2.

The charging cable 4 is a cable for transmitting charging power, a signal, and control power source, where the charging connector 2 and the charger 3 are connected to each other via the charging cable 4. The charging cable 4 is formed of a cabtire cable (tough-rubber sheath cable) in which each of a plurality of electric wires is double insulated with a vinyl sheath. The cabtire cable may be formed of a vinyl sheath with an emphasis on cost or a rubber sheath with an emphasis on handling at low temperature.

The charging cable 4 includes the power line 41, the signal line 42, and a signal line 43. One end of each of the power line 41, the signal line 42, and the signal line 43 is connected to the charging connector 2. Another end of the power line 41 is connected to a DC output end of the power converter 32. Another end of each of the signal line 42 and the signal line 43 is connected to the controller 33.

The signal line 42 is a signal line for transmitting a connection confirmation signal output from the power supply 10 to the controller 33 when the charging connector 2 is connected to the EV 1. The signal line 43 is a signal line for transmitting a connector lock signal, a connector unlock signal, and a solenoid drive signal. The connector lock signal is a signal for locking the charging connector 2 connected to the vehicle power receiving part 11 such that a user cannot remove the charging connector. The connector lock signal is output from the controller 33. The connector unlock signal is a signal for unlocking the charging connector 2, which is connected to the vehicle power receiving part 11 and locked, such that a user can remove the charging connector. The connector unlock signal is output from the controller 33. The solenoid drive signal is a signal indicating that a solenoid in the charging connector 2 is driven. The solenoid drive signal is output from the solenoid in the charging connector 2. Details of the solenoid will be described later.

When the charging connector 2 is connected to the vehicle power receiving part 11 of the EV 1, the power line 41 of the charger 3 is connected to the power line 12 wired inside the EV 1, while the signal line 42 of the charger 3 is connected to the signal line 13 wired inside the EV 1.

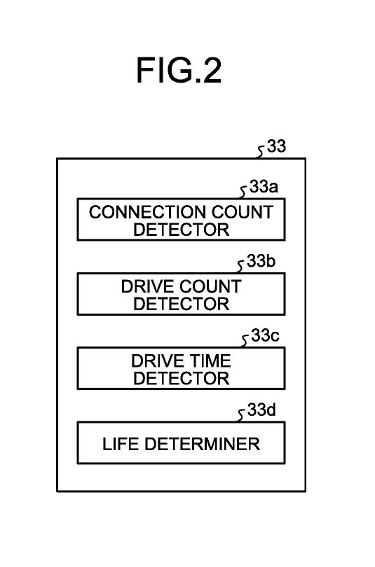

FIG. 2 is a block diagram of the controller of the charger included in the charging system according to the first embodiment. The controller 33 includes: a connection count detector 33a for detecting the number of times the charging connector 2 is connected to the EV 1; a drive count detector 33b for detecting the number of times the solenoid is driven; a drive time detector 33c for detecting time from start to end of drive of the solenoid; and a life determiner 33d for determining whether or not the charging connector 2 has reached the end of life on the basis of at least the number of times the charging connector 2 is connected as detected by the connection count detector 33a.

The life determiner 33d determines whether or not the charging connector 2 has reached the end of life on the basis of not only the number of times the charging connector 2 is connected as detected by the connection count detector 33a, but also the number of times the solenoid is driven as detected by the drive count detector 33b or the time from start to end of drive of the solenoid as detected by the drive time detector 33c.

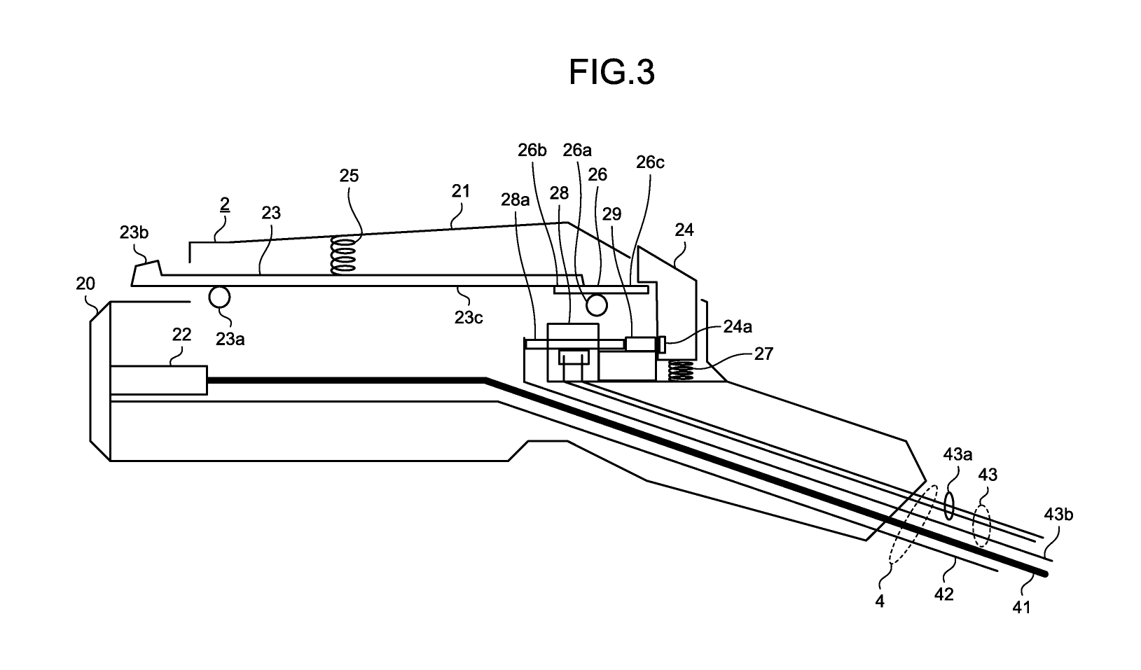

FIG. 3 is a sectional view of the charging connector and the charging cable included in the charging system according to the first embodiment. The charging connector 2 includes: a housing 20 to be fitted to the vehicle power receiving part 11 of the EV 1; a connector case 21 integrally formed with the housing 20 and forming an outer shell of the charging connector 2; a connector pin 22 provided inside the connector case 21 and connected to the power line 41; and a latch 23 provided inside the connector case 21 to pivot about a pivot 23a.

The charging connector 2 further includes: a fit release button 24 for releasing a fitted state between the EV 1 and the charging connector 2; a spring 25 provided inside the connector case 21 and biasing the latch 23; and a lever 26 provided inside the connector case 21 to pivot about a pivot 26a with a movement of the fit release button 24.

The connector case 21 is made of resin or metal having flame retardancy, insulation, and chemical resistance. The connector pin 22 is attached to the tip of the power line 41. The connector pin 22 comes into contact with a metal electrode provided on the side of the vehicle power receiving part 11 when the housing 20 is inserted into the vehicle power receiving part 11 of the EV 1. As a result, the metal electrode provided in the vehicle power receiving part 11 is connected to the power line 41 via the connector pin 22.

The charging connector 2 further includes: a spring 27 provided inside the connector case 21 for pushing back the fit release button 24; a solenoid 28 provided inside the connector case 21 and driven by the connector lock signal and the connector unlock signal; and a slide plate 29 driven by a solenoid driver 28a in the solenoid 28. The solenoid 28 is a component for switching the fit release button 24 to an operable state or an inoperable state and a component for converting electric energy into mechanical motion.

The slide plate 29 is provided at an end of the solenoid driver 28a. When the connector lock signal is output, the slide plate 29 is inserted into an opening 24a of the fit release button 24. When the connector unlock signal is output, the slide plate 29 is pulled out of the opening 24a of the fit release button 24 and operates to release the lock of the charging connector 2.

A protrusion 23b is formed at one end of the latch 23. The protrusion 23b is formed in a wedge shape to be fitted to the vehicle power receiving part 11 illustrated in FIG. 1. Another end 23c of the latch 23 is in contact with one end 26b of the lever 26. The other end 23c of the latch 23 is biased by the spring 25. Another end 26c of the lever 26 is in contact with the fit release button 24.

The signal line 43 in the charging cable 4 includes: a signal line 43a through which the connector lock signal and the connector unlock signal are transmitted; and a signal line 43b through which the solenoid drive signal is transmitted. The signal line 43a and the signal line 43b are connected to the coil of the solenoid 28.

The solenoid 28 includes the solenoid driver 28a for driving the slide plate 29. When the solenoid 28 receives the connector lock signal, the solenoid driver 28a operates to insert the slide plate 29 into the opening 24a of the fit release button 24. When the solenoid 28 receives the connector unlock signal, the solenoid driver 28a operates to pull out the slide plate 29 from the opening 24a of the fit release button 24.

When a user inserts the charging connector 2 into the vehicle power receiving part 11, an inclined plane of the protrusion 23b is brought into contact with the vehicle power receiving part 11, and the latch 23 pivots counterclockwise against the biasing force of the spring 25. At this time, the lever 26 connected to the latch 23 pivots clockwise. The housing 20 is thus fitted to the vehicle power receiving part 11.

When the housing 20 is completely inserted into the vehicle power receiving part 11, the protrusion 23b of the latch 23 is caught in a recess (not illustrated) formed in the vehicle power receiving part 11 so that the charging connector 2 cannot be pulled out in such a state. When the charging connector 2 is to be pulled out, a user pushes down the fit release button 24 to cause the lever 26 to pivot clockwise, and the latch 23 pushed by the lever 26 pivots counterclockwise against the biasing force of the spring 25. As a result, the fitted state between the protrusion 23b and the vehicle power receiving part 11 is released.

The slide plate 29 is inserted into the opening 24a of the fit release button 24 by the operation of the solenoid 28 receiving the connector lock signal. This fixes the movement of the fit release button 24 so that the charging connector 2 can be locked not to be removed from the vehicle power receiving part 11.

When the solenoid driver 28a of the solenoid 28, which has received the connector lock signal, operates, the solenoid 28 outputs the solenoid drive signal to the signal line 43b. The solenoid drive signal output to the signal line 43b is transmitted to the controller 33.

Note that the structure related to locking and unlocking of the charging connector 2 is not limited to the above example as long as the charging connector 2 can be locked and unlocked using the solenoid 28.

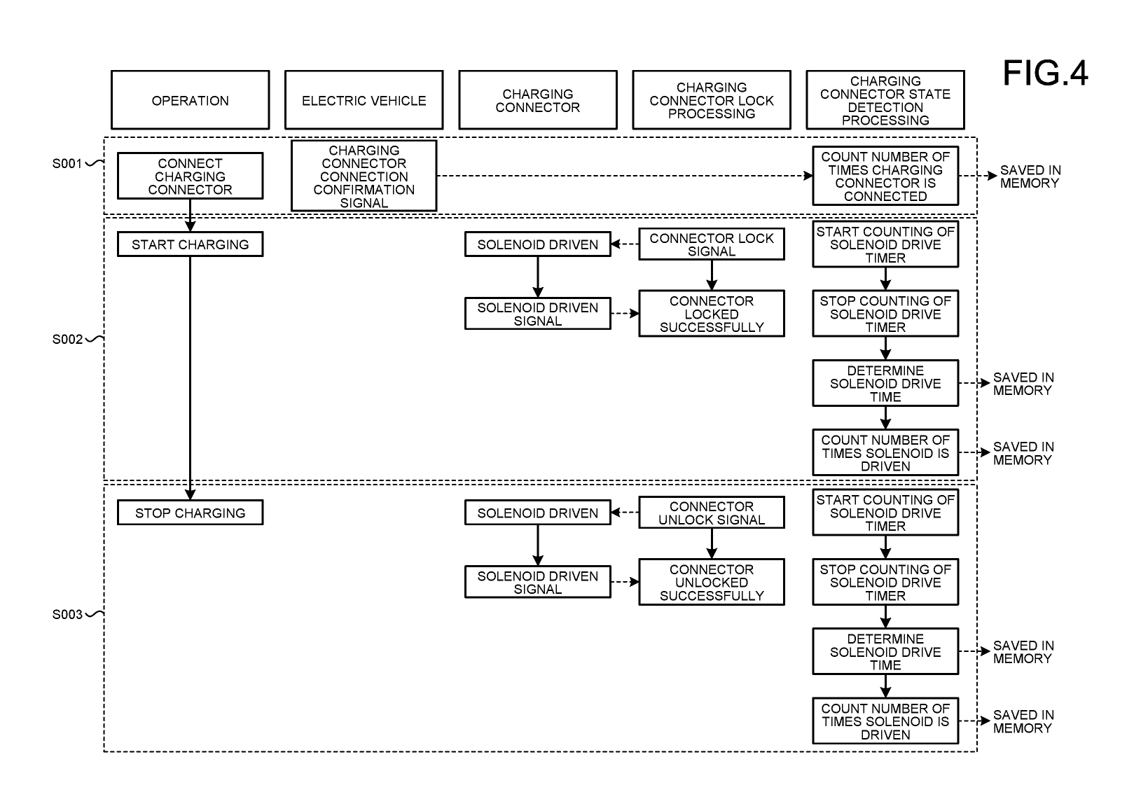

FIG. 4 is a sequence chart of charging connector state detection processing performed in the charging system according to the first embodiment. When the charging connector 2 is connected to the vehicle power receiving part 11 in step S001, the signal line 13 for the connection confirmation signal is connected to the signal line 42, whereby the controller 33 detects that the charging connector 2 is connected to the vehicle power receiving part 11 and counts the number of times the charging connector is connected in the charging connector state detection processing. The controller 33 also saves the charging connector connection count in the memory 35.

In step S002, a charge start command output from a controller (not illustrated) is input to the controller 33, which starts a charging sequence.

When starting the charging, the controller 33 performs charging connector lock processing such that the charging connector 2 does not come off the vehicle power receiving part 11. Specifically, the controller 33 sends the connector lock signal to the solenoid 28 of the charging connector 2 via the signal line 43a to drive the solenoid driver 28a. The controller 33 determines that the connector is successfully locked by detecting the solenoid drive signal that is transmitted through the signal line 43b when the solenoid driver 28a is driven.

The controller 33 also starts counting a solenoid drive timer upon sending the connector lock signal in the charging connector state detection processing. When detecting the solenoid drive signal, the controller 33 stops the counting the solenoid drive timer and determines the solenoid drive time. The solenoid drive time at the start of charging is the time from when the controller 33 transmits the connector lock signal to when the controller 33 detects the solenoid drive signal transmitted at the time the solenoid driver 28a is driven in response to the connector lock signal. The controller 33 saves the solenoid drive time in the memory 35.

When detecting the solenoid drive signal in the charging connector state detection processing, the controller 33 counts the number of times the solenoid is driven and saves solenoid driven count in the memory 35.

In step S003, a charge stop command output from a controller (not illustrated) is input to the charger 3, whereby the controller 33 stops charging of the EV 1.

When stopping the charging, the controller 33 releases the lock of the charging connector 2 in charging connector unlock processing. The controller 33 sends the connector unlock signal to the solenoid 28 of the charging connector 2 via the signal line 43a to drive the solenoid driver 28a. The controller 33 determines that the connector is successfully unlocked by detecting the solenoid drive signal from the signal line 43b when the solenoid driver 28a is driven.

The controller 33 starts counting the solenoid drive timer at the same time as sending the connector unlock signal in the charging connector state detection processing. When detecting the solenoid drive signal, the controller 33 stops the counting of the solenoid drive timer and determines the time taken before the connector is actually locked after sending the connector unlock signal. That is, the time equals the time from when the controller 33 transmits the connector unlock signal to when the controller 33 detects the solenoid drive signal transmitted when the solenoid driver 28a is driven in response to the connector unlock signal. The controller 33 sets this time as the solenoid drive time and saves the solenoid drive time in the memory 35.

When detecting the solenoid drive signal in the charging connector state detection processing, the controller 33 also counts the number of times the solenoid is driven and saves the solenoid driven count in the memory 35.

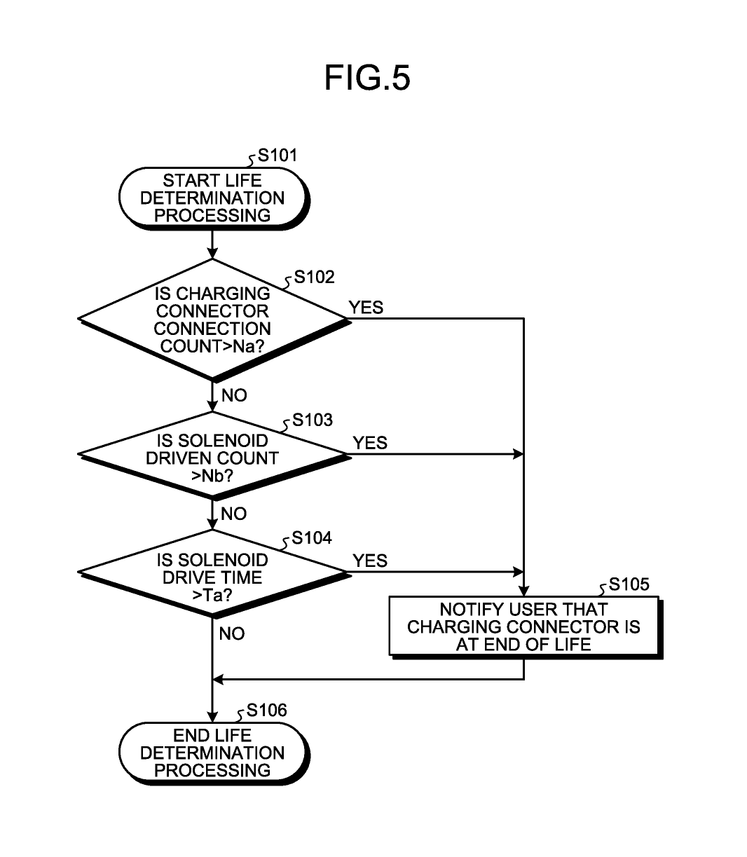

FIG. 5 is a flowchart of charging connector life determination processing performed in the charging system according to the first embodiment. In step S101, the controller 33 starts the charging connector life determination processing.

In step S102, the controller 33 refers to the charging connector connection count saved in the memory 35, and compares the charging connector connection count with a maximum charging connector connection count Na.

If the charging connector connection count exceeds the maximum charging connector connection count Na (Yes in step S102), the controller 33 proceeds to step S105 and causes the display 34 to display message information indicating that the charging connector 2 has reached the end of life, thereby prompting a user to replace the charging connector 2.

If the charging connector connection count does not exceed the maximum charging connector connection count Na (No in step S102), the controller 33 proceeds to step S103 and refers to the solenoid drive count saved in the memory 35 to compare the solenoid drive count with a maximum solenoid drive count Nb.

If the solenoid drive count exceeds the maximum solenoid drive count Nb (Yes in step S103), the controller 33 proceeds to step S105 and causes the display 34 to display a specific message, thereby notifying a user that the charging connector 2 has reached the end of life.

If the solenoid driven count does not exceed the maximum solenoid drive count Nb (No in step S103), the controller 33 proceeds to step S104 and refers to the solenoid drive time saved in the memory 35 to compare the solenoid drive time with a maximum solenoid drive time Ta.

If the solenoid drive time exceeds the maximum solenoid drive time Ta (Yes in step S104), the controller 33 proceeds to step S105 and causes the display 34 to display message information indicating that the charging connector 2 has reached the end of life, thereby prompting a user to replace the charging connector 2.

If the solenoid drive time does not exceed the maximum solenoid drive time Ta (No in step S104), the controller 33 ends the charging connector life determination processing in step S106.

As described above, the charging system 100 according to the first embodiment detects the state of the charging connector 2 to be able to determine, on the basis of the information detected, that the charging connector 2 has reached the end of life by the life determination processing for the charging connector 2. This can reliably prevent a user from using the charging connector 2 beyond its life.

The related art disclosed in Patent Literature 1 includes a locking function to prevent disconnection of the connector during charging, where the number of times the locking is performed also affects the life of the connector and needs to be considered. The charging system 100 according to the first embodiment can determine whether or not the charging connector 2 has reached the end of life in consideration of the solenoid driven count, and can thus determine whether or not the charging connector 2 has reached the end of life more accurately than when only the number of connections of the charging connector 2 is considered.

Moreover, although the related art disclosed in Patent Literature 1 considers heat generation due to an increase in contact resistance, the charging connector is used in a high temperature environment in some cases so that the life determination lacks accuracy as the contact resistance varies depending on the use environment. The charging system 100 according to the first embodiment can determine whether or not the charging connector 2 has reached the end of life in consideration of the charging connector connection count, the solenoid driven count, and the solenoid drive time, thereby being able to accurately determine the life of the charging connector 2 even when the use environment changes.

The charging system 100 according to the first embodiment includes the drive count detector 33b that detects the number of times the solenoid is driven, thereby being able to determine that the number of times the solenoid can be durably driven has been reached and prevent failure to lock the charging connector due to malfunction of the solenoid.

The charging system 100 according to the first embodiment further includes the drive time detector 33c that detects the time from the start to the end of drive of the solenoid, thereby being able to determine an increase in the drive time due to factors associated with aging such as rust on the solenoid and adhesion of foreign matter thereto, and prevent failure to lock the charging connector due to malfunction of the solenoid.

The charging system 100 according to the first embodiment further includes the display to be able to notify a user of abnormality in the charging connector and prevent a decrease in the life of the charging connector by displaying information that urges maintenance of the charging connector.

Moreover, the charging system 100 according to the first embodiment includes the display for notifying that the charging connector has reached the end of life when the life determiner determines that the charging connector has reached the end of life, thereby prompting a user to replace a part of the charging connector to be able to prevent breakage and failure due to aging of the charging connector and increase the safety of the charging connector.

Note that the charging system 100 according to the first embodiment may include a discharge controller that supplies power from the power source of the EV 1 to an electric device or electric equipment.

### Second Embodiment

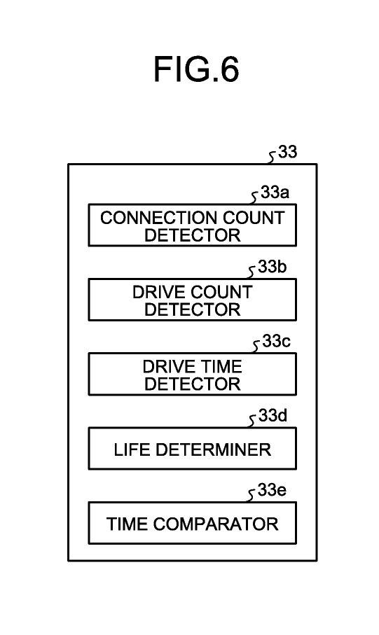

The configuration of the charging system 100 according to a second embodiment is similar to that of the charging system 100 according to the first embodiment except for the operation of the charger 3, whereby the description of the configuration will be omitted. FIG. 6 is a block diagram of the controller of the charger included in the charging system according to the second embodiment. The controller 33 illustrated in FIG. 6 includes a time comparator 33e in addition to the connection count detector 33a, the drive count detector 33b, the drive time detector 33c, and the life determiner 33d.

The time comparator 33e compares the latest solenoid drive time which is a first time detected by the drive time detector 33c with a previous solenoid drive time which is a second time detected by the drive time detector 33c before the first time is detected, and outputs a result of the comparison to the life determiner 33d. On the basis of a time difference between the first time and the second time compared by the time comparator 33e, the life determiner 33d determines the presence or absence of an abnormality in the charging connector 2 that is determined not to be at end of life. Note that the life determination operation performed by the life determiner 33d of the charger 3 according to the second embodiment is similar to that of the first embodiment.

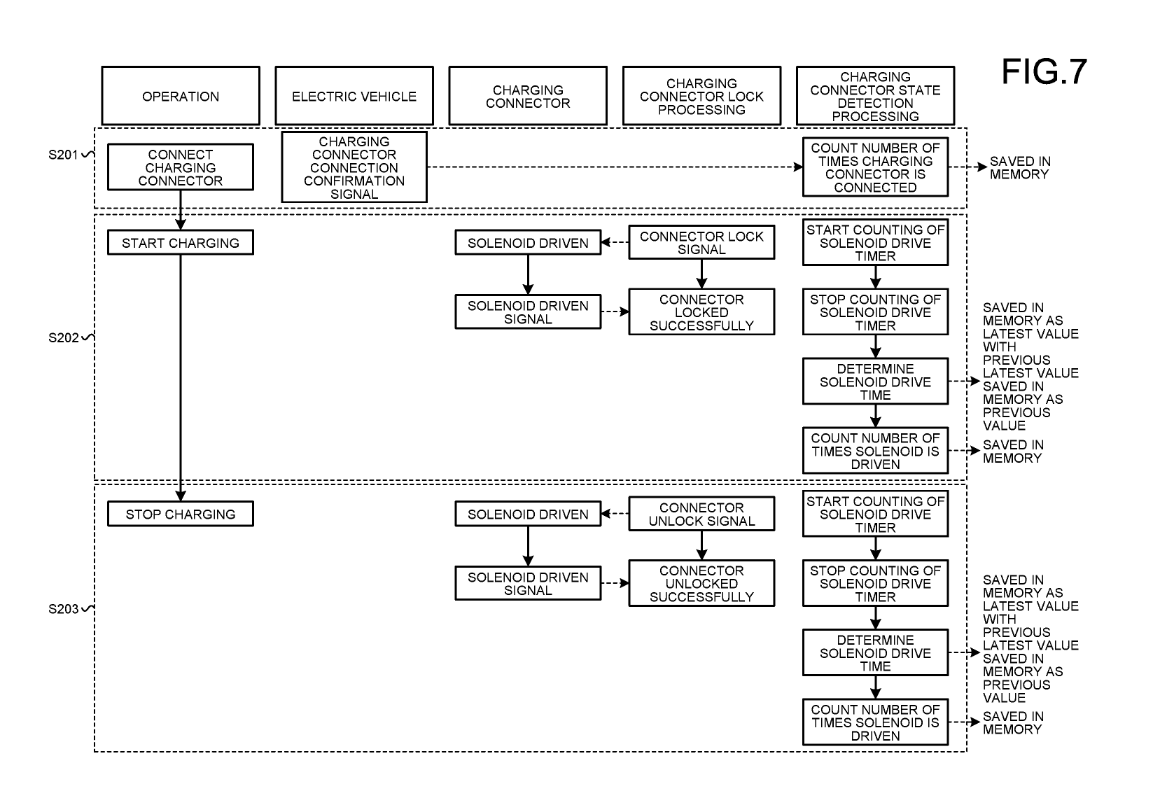

FIG. 7 is a sequence chart of charging connector state detection processing performed in the charging system according to the second embodiment. Differences between the sequence charts of the charging connector state detection processing illustrated in FIGS. 4 and 7 are as follows. Note that except for the differences described below, the sequence chart in FIG. 7 is similar to that of the charging connector state detection processing illustrated in FIG. 4, whereby a description of the similarities will be omitted.

(1) In step S202 of the sequence chart in FIG. 7, the controller 33 saves the solenoid drive time determined at the start of charging as the latest value in the memory 35, and also saves therein the solenoid drive time already stored in the memory 35 as a previous value.

(2) In step S203 of the sequence chart in FIG. 7, the controller 33 saves the solenoid drive time determined at the termination of charging as the latest value in the memory 35, and also saves therein the solenoid drive time already stored in the memory 35 as a previous value.

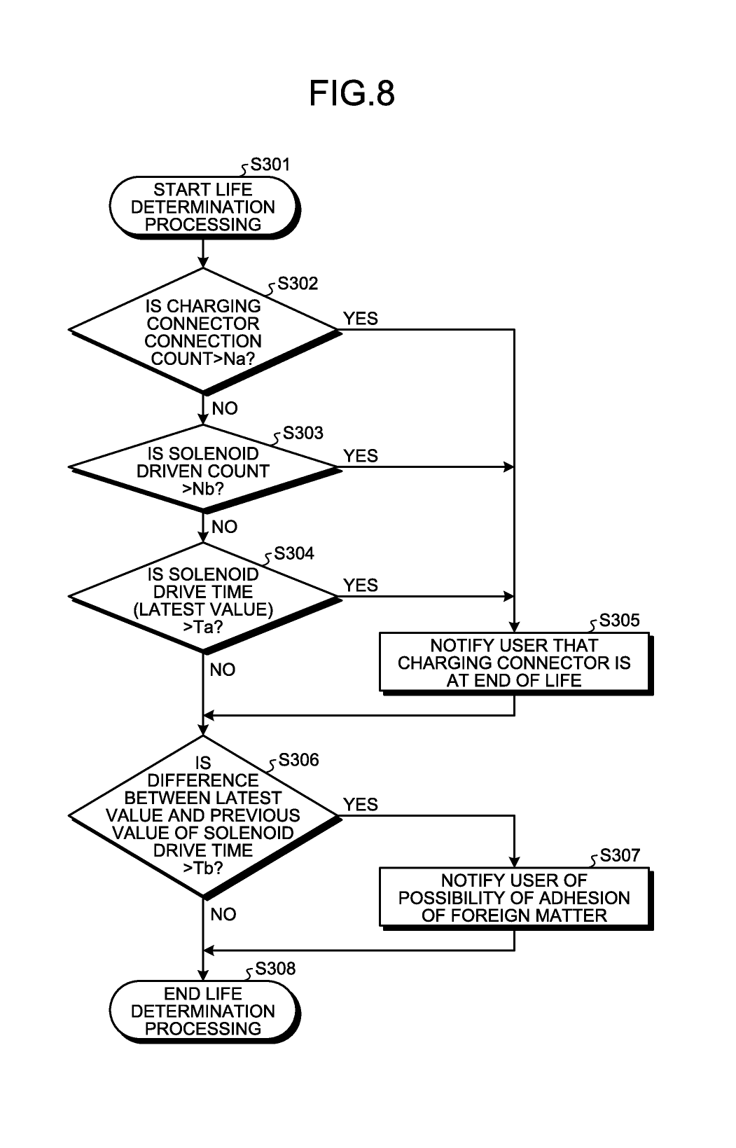

FIG. 8 is a flowchart of charging connector life determination processing performed in the charging system according to the second embodiment. In step S301, the controller 33 starts the charging connector life determination processing.

In step S302, the controller 33 refers to the charging connector connection count saved in the memory 35, and compares the charging connector connection count with the maximum charging connector connection count Na.

If the charging connector connection count exceeds the maximum charging connector connection count Na (Yes in step S302), the controller 33 proceeds to step S305 and causes the display 34 to display message information indicating that the charging connector 2 has reached the end of life, thereby prompting a user to replace the charging connector 2.

If the charging connector connection count does not exceed the maximum charging connector connection count Na (No in step S302), the controller 33 proceeds to step S303 and refers to the solenoid driven count saved in the memory 35 to compare the solenoid driven count with the maximum solenoid driven count Nb.

If the solenoid driven count exceeds the maximum solenoid driven count Nb (Yes in step S303), the controller 33 proceeds to step S305 and causes the display 34 to display message information indicating that the charging connector 2 has reached the end of life, thereby prompting a user to replace the charging connector 2.

If the solenoid driven count does not exceed the maximum solenoid driven count Nb (No in step S303), the controller 33 proceeds to step S304 and refers to the latest value of the solenoid drive time saved in the memory 35 to compare the latest value of the solenoid drive time with the maximum solenoid drive time Ta.

If the latest value of the solenoid drive time exceeds the maximum solenoid drive time Ta (Yes in step S304), the controller 33 proceeds to step S305 and causes the display 34 to display message information indicating that the charging connector 2 has reached the end of life, thereby prompting a user to replace the charging connector 2.

If the latest value of the solenoid drive time does not exceed the maximum solenoid drive time Ta (No in step S304), the controller 33 proceeds to step S306 and refers to the latest value and the previous value of the solenoid drive time saved in the memory 35. The controller 33 then obtains a time difference between the latest value of the solenoid drive time and the previous value of the solenoid drive time, and compares the time difference with a maximum solenoid drive time variation Tb.

If the time difference between the latest value of the solenoid drive time and the previous value of the solenoid drive time exceeds the maximum solenoid drive time variation Tb (Yes in step S306), the solenoid 28 of the charging connector 2 possibly has an abnormality due to foreign matter adhering to the solenoid 28 of the charging connector 2. Thus, in step S307, the controller 33 causes the display 34 to display message information indicating a possibility of foreign matter adhering to the solenoid 28 of the charging connector 2, thereby prompting a user to wash the charging connector 2 with water.

If the time difference between the latest value of the solenoid drive time and the previous value of the solenoid drive time does not exceed the maximum solenoid drive time variation Tb (No in step S306), the controller 33 ends the charging connector life determination processing in step S308.

As described above, the life determiner 33d of the charging system 100 according to the second embodiment determines the presence or absence of an abnormality in the charging connector that is determined not to be at end of life, on the basis of the time difference between the first time and the second time compared by the time comparator 33e. Even when the life of the charging connector 2 cannot be determined accurately due to the use environment of the charging connector 2, the charging system 100 according to the second embodiment can determine an abnormality other than aging of the solenoid and prevent a user from using the charging connector 2 that is determined not to be at end of life due to the use environment of the charging connector 2.

Moreover, the charging system 100 according to the second embodiment observes a change in the solenoid drive time to be able to allow a user to use the charging connector 2 until the charging connector 2 reaches the end of its life. Note that examples of the use environment in which the life of the charging connector 2 may not be able to be determined include a case in which the charging connector 2 is used in an area near a coast where salt adhesion is likely to occur, and a case in which dust accumulates in the solenoid 28 as the solenoid 28 is not driven for a long time.

Furthermore, the charging system 100 according to the second embodiment includes the display for notifying that the charging connector 2 has an abnormality when the life determiner 33d determines that the charging connector 2 has an abnormality, thereby being able to urge a user to perform feasible maintenance and prevent a decrease in the life of the charging connector.

The configuration illustrated in the above embodiment merely illustrates an example of the content of the present invention, and can thus be combined with another known technique or partially omitted and/or modified without departing from the scope of the present invention.

### REFERENCE SIGNS LIST

1 EV; 2 charging connector; 3 charger; 4 charging cable; 5 distribution board; 10 power supply; 11 vehicle power receiver; 12, 41 power line; 13, 42, 43, 43a, 43b signal line; 20 housing; 21 connector case; 22 connector pin; 23 latch; 23a pivot; 23b protrusion; 23c, 26c another end; 24 fit release button; 24a opening; 25, 27 spring; 26 lever; 26a pivot; 26b one end; 28 solenoid; 28a solenoid driver; 29 slide plate; 31 interconnection switch; 32 power converter; 33 controller; 33a connection count detector; 33b drive count detector; 33c drive time detector; 33d life determiner; 33e time comparator; 34 display; 35 memory; 100 charging system; 200 power system.

1. A charging system comprising:
a charger to charge an electric vehicle; and
a charging connector to supply power output from the charger to the electric vehicle, wherein the charging connector includes:
a fit release button to release a fitted state between the electric vehicle and the charging connector; and
a solenoid to switch the fit release button to an operable state or an inoperable state, wherein
the charger includes:
a connection count detector to detect a number of times the charging connector is connected to the electric vehicle;
a life determiner to determine whether or not the charging connector has reached end of life on the basis of at least the number of times the charging connector is connected as detected by the connection count detector; and
a drive count detector to detect the number of times the solenoid is driven, wherein
the life determiner determines whether or not the charging connector has reached the end of life on the basis of the number of times the solenoid is driven when the number of times the charging connector is connected does not exceed a maximum charging connector connection count.

2. (canceled)

3. The charging system according to claim 1, wherein
the charger includes a drive time detector to detect a drive time from a start of drive of the solenoid to an end of drive of the solenoid, and
the life determiner determines whether or not the charging connector has reached the end of life on the basis of the drive time when the number of times the solenoid is driven does not exceed a maximum solenoid driven count.

4. The charging system according to claim 1, wherein the charger includes a display to notify that the charging connector is at end of life when the life determiner determines that the charging connector has reached the end of life.

5. The charging system according to claim 3, wherein
the charger includes a time comparator to compare a first time detected by the drive time detector with a second time detected by the drive time detector before the first time is detected, and
when the drive time does not exceed a maximum solenoid drive time, the life determiner determines whether or not the charging connector determined not to be at end of life has an abnormality on the basis of a time difference between the first time and the second time compared by the time comparator.

6. The charging system according to claim 5, wherein the charger includes a display to notify that the charging connector has an abnormality when the life determiner determines that the charging connector has an abnormality.

7. The charging system according to claim 3, wherein the charger includes a display to notify that the charging connector is at end of life when the life determiner determines that the charging connector has reached the end of life.
